(19) United States
(12) Patent Application Publication
(10) Pub. No.: US 2020/0003812 A1
(43) Pub. Date: Jan. 2, 2020

(54) USING TELEMETRY SIGNALS TO ESTIMATE GREENHOUSE GAS EMISSIONS FOR COMPUTER SERVERS

(71) Applicant: Oracle International Corporation, Redwood Shores, CA (US)

(72) Inventors: Kenny C. Gross, Escondido, CA (US); Sanjeev Sondur, Horsham, PA (US); Richard A. Kroes, Lake Placid, NY (US)

(73) Assignee: Oracle International Corporation, Redwood Shores, CA (US)

(21) Appl. No.: 16/022,269

(22) Filed: Jun. 28, 2018

(51) Int. Cl. G01R 22/10

(52) U.S. Cl. CPC G01R 22/10

(57) ABSTRACT

The disclosed embodiments provide a system that estimates greenhouse gas (GHG) emissions for a server computer system. During operation, the system receives time-series telemetry signals that were gathered from sensors in the server during operation of the server. Next, the system estimates a power consumption for the server based on the received time-series telemetry signals. The system then multiplies the estimated power consumption by a time interval to estimate a power consumption for the server over the time interval. Finally, the system converts the estimated power consumption for the server over the time interval into an estimate for GHG emissions for the server over the time interval.

### BACKGROUND

### Field

The disclosed embodiments generally relate to techniques for estimating greenhouse gas (GHG) emissions resulting from power consumed by computer systems. More specifically, the disclosed embodiments relate to a technique for using telemetry signals to estimate electrical power usage and associated GHG emissions, which result from operating servers in a computer data center.

### Related Art

The “Carbon Disclosure Project” (CDP) organization is presently compelling major publicly traded companies to report the total greenhouse gas (GHG) emissions for all of their products. The CDP advocates that managers of stock funds, pension funds, endowments, and other asset owners only channel their investments into public companies who have high “GHG reporting compliance” scores. Moreover, companies with low “GHG reporting compliance” scores are implicated as contributing to global climate change. The negative consequences of not reporting GHG emissions to the CDP are significant, and can materially decrease a public company's share price. As of 2017, the CDP's approach has resulted in 92% of the Fortune-500 companies reporting GHG emissions for their products.

For enterprise server products, the existing technique for estimating GHG emissions proceeds as follows. Companies typically use an existing “power calculator” to estimate the power usage for a server. Server manufacturers typically publish a power calculator, which allows customers to input system configuration information, such as the number of central processing units (CPUs), the number and size of memory modules, the number and size of I/O cards, and the number and size of hard disk drives and/or solid-state drives. Based on these inputs, the power calculator produces a deliberately conservative overestimate of the power the server will draw when the server is running maximum workloads. The reason that the published power calculators deliberately overestimate power consumption is that customers generally use the power calculator estimates to determine circuit-breaker limits for racks of servers in their data centers. If a server manufacturer establishes a circuit-breaker limit which is too low, and as a result brings down a rack of servers, the economic consequences and business liability can be substantial.

After the power usage is estimated, the estimate is multiplied by the lifetime of the server to estimate the total power consumption for each server. This estimated total power consumption is summed across the population of that class of servers in the field. Finally, the total estimated power usage for all of the servers is converted into metric tons of carbon using an established conversion formula.

This technique for estimating GHG emissions is not only overly conservative because of the worst-case estimates from the power calculators, but also because servers rarely run close to their rated workload capacities. For example, in the finance industry, typical utilization factors for enterprise servers are under 20%. However, the above-described approach computes the same GHG emissions for a server in the finance industry with a 20% utilization factor as for a server in a high-performance computing data center with a 99% utilization factor. Hence, what is needed is technique for estimating GHG emissions for enterprise servers, which does not suffer from the overly conservative assumptions of existing techniques.

### SUMMARY

The disclosed embodiments provide a system that estimates greenhouse gas (GHG) emissions for a server computer system. During operation, the system receives time-series telemetry signals that were gathered from sensors in the server during operation of the server. Next, the system estimates a power consumption for the server based on the received time-series telemetry signals. The system then multiplies the estimated power consumption by a time interval to estimate a power consumption for the server over the time interval. Finally, the system converts the estimated power consumption for the server over the time interval into an estimate for GHG emissions for the server over the time interval.

In some embodiments, the server is located in a data center, and the system additionally sums the individual power consumptions for each server in the data center and associated components to produce an estimate for GHG emissions for the entire data center.

In some embodiments, while estimating the power consumption for the server, the system accounts for power consumption during a percentage of time that the server is active and performing useful computations, and a percentage of time that the server is idle.

In some embodiments, while estimating the power consumption for the server, the system uses an inferential model to estimate the power consumption based on serial correlation and/or cross-correlation among signals in the time-series telemetry signals, wherein the inferential model was previously trained using time-series telemetry signals generated by the server while the server was hooked up to a power meter to establish ground truth values for power consumption.

In some embodiments, the inferential model is a multivariate state estimation technique (MSET) model.

In some embodiments, while estimating the power consumption for the server, the system multiplies voltage signals and corresponding current signals for components in the server to determine individual power consumptions for the components. Next, the system sums the individual power consumptions for the components to estimate the power consumption for the server.

In some embodiments, while estimating the power consumption for the server, the system multiplies: a voltage v, a current i, and a calibration factor k to produce an estimation for the power consumption, wherein the calibration factor k varies based on a present power consumption level for the server.

In some embodiments, the calibration factor k is generated by an inferential model, which uses serial correlation and/or cross-correlation among signals in the time-series telemetry signals to generate k, wherein the inferential model was previously trained using time-series telemetry signals generated by the server while the server was hooked up to a power meter to establish ground truth values for power consumption.

In some embodiments, converting the estimated power consumption for the server into the estimated GHG emissions involves using a region-specific conversion factor, which is scaled based on types of power plants that are used to generate power in a region where the server operates.

In some embodiments, the system additionally uses the estimate for GHG emissions for the server to calculate a corresponding carbon tax.

### BRIEF DESCRIPTION OF THE FIGURES

FIG. 1 illustrates a GHG estimation system in accordance with the disclosed embodiments.

FIG. 2 illustrates an exemplary Black Box Recorder (BBR) system for storing telemetry signals in accordance with one embodiment of the present invention.

FIG. 3 illustrates a telemetry data archiving system, which records both short-term real-time performance data and long-term historical performance data, in accordance with an embodiment of the present invention.

FIG. 4 presents a flow chart illustrating the process for estimating GHG emissions for a server computer system in accordance with the disclosed embodiments.

### DETAILED DESCRIPTION

The following description is presented to enable any person skilled in the art to make and use the present embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present embodiments. Thus, the present embodiments are not limited to the embodiments shown, but are to be accorded the widest scope consistent with the principles and features disclosed herein.

The data structures and code described in this detailed description are typically stored on a computer-readable storage medium, which may be any device or medium that can store code and/or data for use by a computer system. The computer-readable storage medium includes, but is not limited to, volatile memory, non-volatile memory, magnetic and optical storage devices such as disk drives, magnetic tape, CDs (compact discs), DVDs (digital versatile discs or digital video discs), or other media capable of storing computer-readable media now known or later developed.

The methods and processes described in the detailed description section can be embodied as code and/or data, which can be stored in a computer-readable storage medium as described above. When a computer system reads and executes the code and/or data stored on the computer-readable storage medium, the computer system performs the methods and processes embodied as data structures and code and stored within the computer-readable storage medium. Furthermore, the methods and processes described below can be included in hardware modules. For example, the hardware modules can include, but are not limited to, application-specific integrated circuit (ASIC) chips, field-programmable gate arrays (FPGAs), and other programmable-logic devices now known or later developed. When the hardware modules are activated, the hardware modules perform the methods and processes included within the hardware modules.

### Overview

The disclosed embodiments provide a system, which implements a new automated technique for computing GHG emissions. During operation, the system computes (in real time) the power consumed by all components in a server, and then integrates these dynamic power traces to obtain total consumed energy in kilowatt hours (kWhs) versus time. The system then aggregates the consumed energy across all components in the server, and converts the consumed energy into GHG emission equivalents, using a default GHG-emission conversion factor, and optionally allows the customer to supply a data-center-specific GHG-emission conversion factor if that data center uses ecologically friendly power sources, such as from solar panels or other renewable sources.

During operation, the system makes use of an innovation called a Black Box Recorder (BBR), which contains a lifetime history of telemetry signatures for all internal temperatures, voltages, currents, fan-speeds, and power sensors throughout the server. (For example, see U.S. Pat. No. 7,281,112, entitled “Real Time Power Harness: Power Monitoring for Computers via Telemetry” by inventors Kenny C. Gross, et al., filed on 28 Feb. 2005, which is hereby incorporated herein by reference, and is referred to as “the '112 patent.” Also see U.S. Pat. No. 7,197,411, entitled “Real Time Power Harness” by inventors Kenny C. Gross, et al., filed on 27 Mar. 2007, which is hereby incorporated herein by reference.)

While computing GHG emissions, the system sifts through BBR files and extracts long-term history (LTH) data sets and builds a power-versus-time history from these data sets. The system then integrates the power-versus-time history to produce a cumulative-consumed-energy profile for each server. In doing so, the system computes the “area under the curve” (i.e., the integral of power versus “up time” for each server, which yields “consumed energy” in kWhs. The system then aggregates kWh metrics across all IT assets in the data center. Next, the system adds in cooling energy, and converts these power-consumption values into corresponding CO₂ values, using either an average default CO₂ conversion factor for all utilities, or alternatively a region-specific CO₂ conversion factor based on customer location information, which is stored in the same “snapshot” from which the BBR files are extracted.

The system can use a published region-specific CO₂ conversion factor, which is specific to the types of power plants that provide power in the specific geographical region in which the data center is operating. Note that some types of power plants produce more CO₂ per kilowatt hour than other types of power plants. This region-specific conversion factor is important because it accounts for the “greenness versus brownness” of the power that is generated in a specific region.

The above-described new “BBR sifter” technique for computing CO₂ emissions produces more realistic and lower CO₂ numbers than the existing “power calculator” technique, which is used by most server vendors. Note that the power calculator technique is overly conservative by design. Also, the power calculator technique does not account for the fact that the servers may be turned off, or may be virtualized to a quiescent state by increasingly popular virtualization mechanisms.

### GHG Estimation System

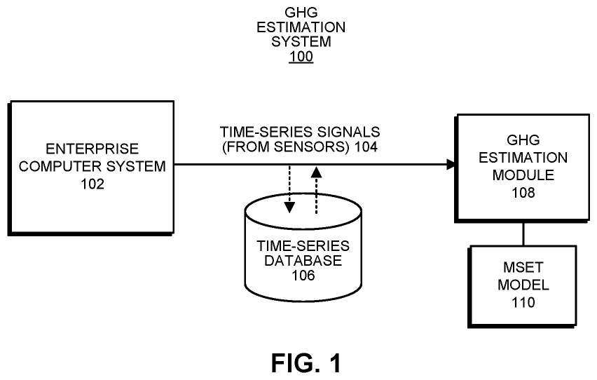

FIG. 1 illustrates an exemplary GHG estimation system 100 in accordance with the disclosed embodiments. During operation of the system illustrated in FIG. 1, time-series signals 104 are obtained from sensors in an enterprise computing system 102, where the enterprise computing system 102 includes one or more servers and related IT assets. These time-series signals 104 are stored into a time-series database 106, such as in the BBR system described in the '112 patent referenced above.

Information from time-series database 106 in the BBR system is processed by GHG estimation module 108, which estimates GHG emissions using the technique described above.

In some embodiments, GHG estimation module 108 makes use of an MSET model 110 to learn correlations between aggregate power consumption and voltages and currents. In these embodiments, while estimating the power consumption for a server, the system multiplies: a voltage v, a current i, and a calibration factor k to produce an estimate for the power consumption, wherein the calibration factor k varies based on a present aggregate power consumption level for the server. This calibration factor k is generated by an inferential MSET model, which uses serial correlation and/or cross-correlation among signals in the time-series telemetry signals to generate k. Note that the MSET model was previously trained using time-series telemetry signals generated by enterprise computing system 102, while components in enterprise computing system 102 were hooked up to a power meter to establish ground truth values for power consumption. (For a description of MSET, see U.S. Pat. No. 7,181,651, entitled “Detecting and Correcting a Failure Sequence in a Computer System Before a Failure Occurs,” by inventors Kenny C. Gross, et al., filed on 11 Feb. 2004, which is hereby incorporated herein by reference.) Although it is advantageous to use MSET for pattern-recognition purposes, the disclosed embodiments can generally use any one of a generic class of pattern-recognition techniques called nonlinear, nonparametric (NLNP) regression, which includes neural networks, support vector machines (SVMs), auto-associative kernel regression (AAKR), and even simple linear regression (LR).

### BBR System

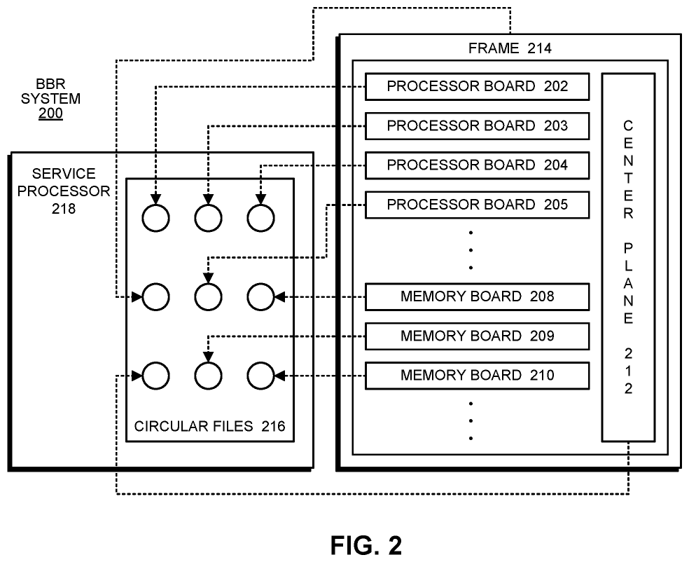

FIG. 2 illustrates an exemplary BBR system 200, which includes a service processor 218 for processing telemetry signals, in accordance with one embodiment of the present invention. As is illustrated in FIG. 2, BBR system 200 includes a number of processor boards 202-205 and a number of memory boards 208-210, which communicate with each other through center plane 212. These system components are all housed within a frame 214.

In some embodiments, these system components and frame 214 are all field replaceable units (FRUs), which are independently monitored as is described below. Note that all major system units, including both hardware and software, can be decomposed into FRUs. For example, a software FRU can include an operating system, a middleware component, a database, or an application.

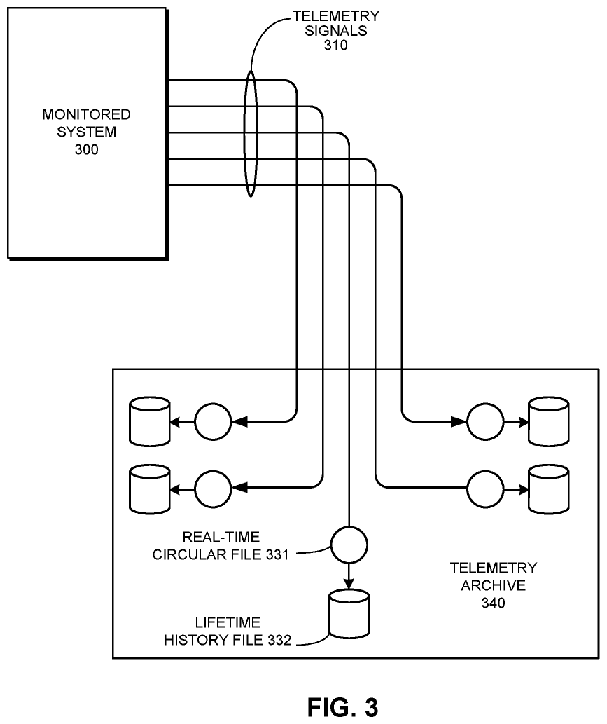

BBR system 200 includes a service processor 218, which can be located within BBR system 200, or alternatively can be located in a standalone unit separate from computer system 200. Service processor 218 performs a number of diagnostic functions for computer system 200. One of these diagnostic functions involves recording performance parameters from the various FRUs within computer system 200 into a set of circular files 216, which are located within service processor 218. In some embodiments, there exists one dedicated circular file for each FRU. Note that this circular file can have a dual-stage structure as is described below with reference to FIG. 3.

Storing Infinite Performance Data with Finite Storage Space

In general, it is desirable to retain all of the collected time-series telemetry data. For example, a system can capture the time-series telemetry signals in a BBR file. This BBR file retains time-series telemetry signals collected during a preceding time interval. One challenge, however, is to provide sufficient storage space for the BBR file, because the BBR file can potentially grow infinitely. One way to cope with this problem is to use a circular file structure, which retains only the last x days' worth of data. The drawback of using a fixed-size circular file is that one loses the long-term trend behavior of the signals. On the other hand, if one allows the BBR file to grow infinitely, the file may eventually crash the storage system.

To resolve this problem, the system adopts a two-tier file system, which includes a real-time circular file and a lifetime history file. Both of these files have finite sizes. The real-time circular file stores real-time performance data for a limited amount of time (e.g., for seven days). When the real-time circular file is full, its data is consolidated and transferred to the lifetime history file. During operation, the system recurrently compresses the data stored in the lifetime history file, thereby allowing more data to be stored in the future.

For example, FIG. 3 illustrates a telemetry data archiving system which records both short-term real-time performance data and long-term historical performance data. In this exemplary system, a number of time-series telemetry signals 310 from computer system 300 are monitored.

After being received, telemetry signals 310 are sent to a telemetry archive 340. Within telemetry archive 340, each telemetry signal is recorded in a real-time circular file and subsequently a lifetime history file. As shown in FIG. 3, real-time circular file 331 saves the real-time data for one time-series telemetry signal. When real-time circular file 331 is full, its data is consolidated and transferred to a corresponding lifetime history file 332.

In some embodiments, the lifetime history file compresses its data when it is full. One compression method is to compute an ensemble average of every two successive data points, and to replace these two data points with a new data point whose value is the ensemble average thereof. One can alternatively use other compression methods, such as discarding every other data point. However, replacing two data points with their average is beneficial because it retains characteristics of the original signal to a certain degree. For example, if there is a very narrow spike in the original signal that lasts for only one sampling interval, discarding every other data point would result in a 50% probability of losing the spike. Conversely, taking ensemble averages of adjacent data pairs can preserve the spike, even if the averaging process reduces the amplitude of the spike.

### Process for Estimating GHG Emissions

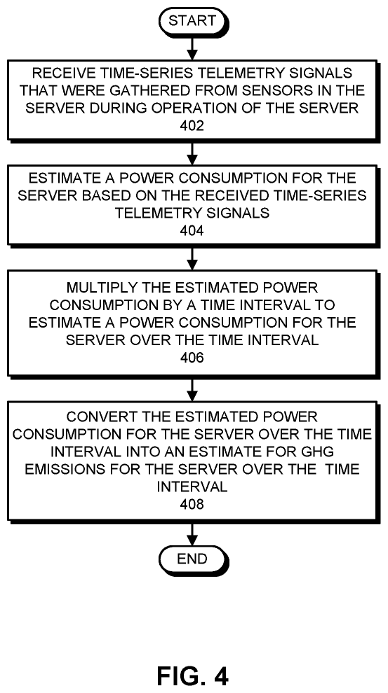

FIG. 4 presents a flow chart illustrating a process for estimating

GHG emissions for a server computer system. During operation, the system receives time-series telemetry signals that were gathered from sensors in the server during operation of the server (step 402). Next, the system estimates a power consumption for the server based on the received time-series telemetry signals (step 404). The system then multiplies the estimated power consumption by a time interval to estimate a power consumption for the server over the time interval (step 406). Finally, the system converts the estimated power consumption for the server over the time interval into an estimate for GHG emissions for the server over the time interval (step 408).

Various modifications to the disclosed embodiments will be readily apparent to those skilled in the art, and the general principles defined herein may be applied to other embodiments and applications without departing from the spirit and scope of the present invention. Thus, the present invention is not limited to the embodiments shown, but is to be accorded the widest scope consistent with the principles and features disclosed herein.

The foregoing descriptions of embodiments have been presented for purposes of illustration and description only. They are not intended to be exhaustive or to limit the present description to the forms disclosed. Accordingly, many modifications and variations will be apparent to practitioners skilled in the art. Additionally, the above disclosure is not intended to limit the present description. The scope of the present description is defined by the appended claims.

What is claimed is:

1. A method for estimating greenhouse gas (GHG) emissions for a server computer system, comprising:
receiving time-series telemetry signals that were gathered from sensors in the server during operation of the server;
estimating a power consumption for the server based on the received time-series telemetry signals;
multiplying the estimated power consumption by a time interval to estimate a power consumption for the server over the time interval; and
converting the estimated power consumption for the server over the time interval into an estimate for GHG emissions for the server over the time interval.

2. The method of claim 1,
wherein the server is located in a data center; and
wherein the method further comprises summing individual power consumptions for each server in the data center and associated components to produce an estimate for GHG emissions for the entire data center.

3. The method of claim 1, wherein estimating the power consumption for the server involves accounting for power consumption during a percentage of time that the server is active and performing useful computations, and a percentage of time that the server is idle.

4. The method of claim 1, wherein estimating the power consumption for the server comprises using an inferential model to estimate the power consumption based on serial correlation and/or cross-correlation among signals in the time-series telemetry signals, wherein the inferential model was previously trained using time-series telemetry signals generated by the server while the server was hooked up to a power meter to establish ground truth values for power consumption.

5. The method of claim 4, wherein the inferential model is a multivariate state estimation technique (MSET) model.

6. The method of claim 1, wherein estimating the power consumption for the server comprises:
multiplying voltage signals and corresponding current signals for components in the server to determine individual power consumptions for the components; and
summing the individual power consumptions for the components to estimate the power consumption for the server.

7. The method of claim 1, wherein estimating the power consumption for the server comprises multiplying: a voltage v, a current i, and a calibration factor k to produce an estimation for the power consumption, wherein the calibration factor k varies based on a present power consumption level for the server.

8. The method of claim 7, wherein the calibration factor k is generated by an inferential model, which uses serial correlation and/or cross-correlation among signals in the time-series telemetry signals to generate k, wherein the inferential model was previously trained using time-series telemetry signals generated by the server while the server was hooked up to a power meter to establish ground truth values for power consumption.

9. The method of claim 1, wherein converting the estimated power consumption for the server into the estimated GHG emissions involves using a region-specific conversion factor, which is scaled based on types of power plants that are used to generate power in a region where the server operates.

10. The method of claim 1, wherein the method further comprises using the estimate for GHG emissions for the server to calculate a corresponding carbon tax.

11. A non-transitory, computer-readable storage medium storing instructions that when executed by a computer cause the computer to perform a method for estimating greenhouse gas (GHG) emissions for a server computer system, the method comprising:
receiving time-series telemetry signals that were gathered from sensors in the server during operation of the server;
estimating a power consumption for the server based on the received time-series telemetry signals;
multiplying the estimated power consumption by a time interval to estimate a power consumption for the server over the time interval; and
converting the estimated power consumption for the server over the time interval into an estimate for GHG emissions for the server over the time interval.

12. The non-transitory, computer-readable storage medium of claim 11,
wherein the server is located in a data center; and
wherein the method further comprises summing individual power consumptions for each server in the data center and associated components to produce an estimate for GHG emissions for the entire data center.

13. The non-transitory, computer-readable storage medium of claim 11, wherein estimating the power consumption for the server involves accounting for power consumption during a percentage of time that the server is active and performing useful computations, and a percentage of time that the server is idle.

14. The non-transitory, computer-readable storage medium of claim 11, wherein estimating the power consumption for the server comprises using an inferential model to estimate the power consumption based on serial correlation and/or cross-correlation among signals in the time-series telemetry signals, wherein the inferential model was previously trained using time-series telemetry signals generated by the server while the server was hooked up to a power meter to establish ground truth values for power consumption.

15. The non-transitory, computer-readable storage medium of claim 14, wherein the inferential model is a multivariate state estimation technique (MSET) model.

16. The non-transitory, computer-readable storage medium of claim 11, wherein estimating the power consumption for the server comprises:
multiplying voltage signals and corresponding current signals for components in the server to determine individual power consumptions for the components; and
summing the individual power consumptions for the components to estimate the power consumption for the server.

17. The non-transitory, computer-readable storage medium of claim 11, wherein estimating the power consumption for the server comprises multiplying: a voltage v, a current i, and a calibration factor k to produce an estimation for the power consumption, wherein the calibration factor k varies based on a present power consumption level for the server.

18. The non-transitory, computer-readable storage medium of claim 17, wherein the calibration factor k is generated by an inferential model, which uses serial correlation and/or cross-correlation among signals in the time-series telemetry signals to generate k, wherein the inferential model was previously trained using time-series telemetry signals generated by the server while the server was hooked up to a power meter to establish ground truth values for power consumption

19. The non-transitory, computer-readable storage medium of claim 11, wherein converting the estimated power consumption for the server into the estimated GHG emissions involves using a region-specific conversion factor, which is scaled based on types of power plants that are used to generate power in a region where the server operates.

20. A system that preprocesses time-series sensor data by filling in missing values with corresponding imputed values, comprising:
at least one processor and at least one associated memory; and
an estimation mechanism that executes on the at least one processor, wherein during operation, the estimation mechanism:
receives time-series telemetry signals that were gathered from sensors in the server during operation of the server;
estimates a power consumption for the server based on the received time-series telemetry signals;
multiplies the estimated power consumption by a time interval to estimate a power consumption for the server over the time interval; and
converts the estimated power consumption for the server over the time interval into an estimate for GHG emissions for the server over the time interval.
